(19) United States
(12) Patent Application Publication
(10) Pub. No.: US 2025/0331356 A1
(43) Pub. Date: Oct. 23, 2025

(54) PEROVSKITE BASED PHOTOVOLTAIC CELLS AND PROCESS FOR PREPARING THE SAME

(71) Applicant: ENI S.P.A., Roma (IT)

(72) Inventors: Paolo BIAGINI, Novara (NO) (IT); Riccardo PO', Novara (NO) (IT); Antonella GIURI, Salice Salentino (LE) (IT); Aurora RIZZO, Lecce (LE) (IT); Silvia COLELLA, Bari (BA) (IT); Katia SPARNACCI, Alessandria (AL) (IT)

(21) Appl. No.: 18/873,531

(22) PCT Filed: Jun. 8, 2023
(86) PCT No.: PCT/IB2023/055929

§ 371 Date: Dec. 10, 2024

(30) Foreign Application Priority Data
Jun. 10, 2022 (IT) 102022000012323

(51) Int. Cl. H10K 30/40; H10K 85/10; H10K 85/20; H10K 85/50

(52) U.S. Cl. CPC H10K 30/40; H10K 85/111; H10K 85/115; H10K 85/141; H10K 85/151; H10K 85/215; H10K 85/50

(57) ABSTRACT

A perovskite-based photovoltaic cell (or solar cell) wherein the perovskite photoactive layer includes at least one partially neutralized polyacrylic acid in an amount greater than or equal to 3% by weight, preferably between 4% by weight and 15% by weight, more preferably between 4.5% by weight and 12% by weight, with respect to the total weight of the perovskite precursors.

The perovskite-based photovoltaic cell (or solar cell) can be advantageously used in various applications which require the production of electricity through the exploitation of light energy, in particular of solar radiation energy such as, for example: architecturally integrated photovoltaic systems (Building Integrated Photo Voltaic—BIPV); photovoltaic windows; greenhouses; photo-bioreactors; noise barriers; lighting engineering; design; advertising; automobile industry. The perovskite-based photovoltaic cell (or solar cell) can be used both in stand-alone mode and in modular systems.

### CROSS-REFERENCE TO RELATED APPLICATIONS

This application is a 35 U.S.C. § 371 National Stage patent application of PCT/IB2023/055929 filed 8 Jun. 2023, which claims the benefit of Italian patent application 102022000012323 filed 10 Jun. 2022, the disclosures of which are incorporated herein by reference in their entirety.

### DESCRIPTION

The present disclosure relates to perovskite-based photovoltaic cells (or solar cells).

More specifically, the present disclosure relates to a perovskite-based photovoltaic cell (or solar cell) wherein the photoactive layer of perovskite comprises at least one partially neutralized polyacrylic acid in an amount greater than or equal to 3% by weight, preferably comprised between 4% by weight and 15% by weight, more preferably comprised between 4.5% by weight and 12% by weight, with respect to the total weight of perovskite precursors.

Said perovskite-based photovoltaic cell (or solar cell) can be advantageously used in various applications which require the production of electricity through the exploitation of light energy, in particular of solar radiation energy such as, for example: architecturally integrated photovoltaic systems (Building Integrated Photo Voltaic—BIPV); photovoltaic windows; greenhouses; photo-bioreactors; noise barriers; lighting engineering; design; advertising; automobile industry. Said perovskite-based photovoltaic cell (or solar cell) can be used both in stand-alone mode and in modular systems.

The present disclosure also relates to a process for the preparation of said perovskite-based photovoltaic cell (or solar cell).

The present disclosure is also a composition comprising at least one perovskite and at least one partially neutralized polyacrylic acid in an amount greater than or equal to 3% by weight, preferably comprised between 4% by weight and 15% by weight, more preferably comprised between 4.5% by weight and 12% by weight, based on the total weight of the perovskite precursors.

### BACKGROUND

Photovoltaic cells (or solar cells) are devices capable of converting the energy of light radiation into electrical energy. Currently, most of the photovoltaic cells (or solar cells) that can be used for practical applications exploit the chemical-physical properties of inorganic type photoactive materials, especially high purity crystalline silicon. However, said photovoltaic cells (or solar cells), while providing interesting performances, particularly in terms of efficiency and durability, have also shown some drawbacks. For example, the stiffness and weight of said silicon-based photovoltaic cells (or solar cells) often make it necessary to install an ad hoc frame for their positioning and in fact severely limits their fields of use.

Some of the aforementioned drawbacks can be overcome by using photovoltaic cells (or solar cells) based on organic polymers (Organic Photovoltaics—OPVs) or based on perovskites (Perovskite Solar Cells—PSCs).

In particular, perovskite-based photovoltaic cells (or solar cells) (Perovskite Solar Cells—PSCs) have rapidly become, in recent years, a promising alternative as they combine high power conversion efficiency (PCE) which, currently, has reached a certified value of 25.5%, a series of typical characteristics of photovoltaic cells (or solar cells) based on organic polymers (Organic Photovoltaics—OPVs) thin film such as, for example, the lightness, flexibility and simplicity of the manufacturing process, which starting from suitable mixtures of the various precursors, can allow the production of photovoltaic cells (or solar cells) through well-known and consolidated printing processes (also continuous) in mild conditions and with sustainable costs.

However, perovskite-based photovoltaic cells (or solar cells) (Perovskite Solar Cells—PSCs) can also have some drawbacks such as, for example, the high sensitivity of perovskites towards atmospheric agents (in particular humidity), a non-optimal packing of the perovskitic crystalline phase which negatively affects the transport of charges.

In order to solve the aforementioned drawbacks, numerous research groups have developed various techniques for the construction of perovskite-based photovoltaic cells (or solar cells) (Perovskite Solar Cells—PSCs) which include, for example, the use of polymer additives within the perovskite photoactive layer.

Over the last few years many polymers with both thermoplastic and elastomeric characteristics, both hydrophobic and hydrophilic, have been employed and the results have been summarized in the review by Kim K. et al, “Solar RRL” (2021), Vol. 5, pg. 2000783, doi.org/10.1002/solr.202000783. This review describes the role and contribution of polymeric additives in perovskite-based solar cells. In particular, the use of polymers or polymeric materials as additives is disclosed in order to promote the nucleation and crystallization of the photoactive layers of perovskite so as to increase the particle size of the perovskite crystals. Thanks to their high molecular weight, said polymers allow to obtain a good passivation of the defects present on the edges of the perovskite crystals. Furthermore, said polymers, by limiting the growth rate of the perovskite crystals, can cause an increase in their particle sizes thus allowing for better packing between them. Furthermore, some polymers function as charge carrier materials in the interfacial layers thereby effectively separating the charge carriers and reducing charge recombination. Furthermore, some hydrophobic polymers can protect the perovskite photoactive layers from moisture, while elastomeric polymers can contribute to the mechanical resilience of the perovskite photoactive layer through cross-linking and self-healing.

Ko Y. et al., in “Synthetic Metals” (2019), Vol. 249, pg. 47-51, report a process for the fabrication of perovskite-based solar cells with the following layout: c-TiO₂/MAPbI₃₋ₓClₓ-PMMA/PTAA/Au. The process involves depositing of a layer of a mixture of PbI₂ and PbCl₂, subsequently the substrate obtained is immersed in a solution containing MAI (20 mg/ml) and PMMA (the amount of PMMA is very low, about 1/4000 by weight with respect to MAI) obtaining the formation of the perovskite crystalline phase in the presence of PMMA. Said process allows perovskite-based solar cells to be obtained having a power conversion efficiency (PCE) equal to 15.3%, thanks to an improvement in the charge transport capacity which is associated with an improvement in the morphology and crystallinity of the perovskite photoactive layer. However, it is believed that the aforementioned manufacturing process can be very complicated and difficult to use in the scaling up phase for the construction of large area photovoltaic cells (or solar cells), as it provides for the formation of the photoactive layer of perovskite in two steps. Furthermore, since with the process described above it is not possible to determine the amount of PMMA, which is effectively incorporated in the perovskite photoactive layer, said process probably does not guarantee good reproducibility of the results.

Saraf R. et al., in “ACS Applied Energy Materials” (2019), Vol. 2, pg. 2214-2222, report a process for the fabrication of perovskite-based solar cells with the following layout: ZnO/MAPbI₃-PS/spiro-OMeTAD/Au. The process involves depositing of a perovskite photoactive layer from equimolar solutions of PbI₂ and MAI containing various amounts of polystyrene (PS) (from 0.5% by weight to 14% by weight). Operating under the most favorable conditions (i.e. PS=1% by weight), said process allows to obtain perovskite-based solar cells having a power conversion efficiency (PCE) equal to 12.27%, thanks to the increase in the size of the particle granulometry of the perovskite crystals determined by a better crystallization kinetics. However, it is believed that the aforementioned manufacturing process is not suitable for use in the scaling up phase for the construction of large area photovoltaic cells (or solar cells), as it provides for an annealing step at 200° C. for the formation of the ZnO layer and a two-step process, with the addition of a non-solvent, for the formation of the perovskite photoactive layer: the latter process, in addition to complicating the perovskite film deposition process, can also generate poor reproducibility. Furthermore, according to what reported by the authors, it appears that the polystyrene solutions in the presence of PbI₂ are not stable and give rise to the formation of partially cross-linked polymeric materials and, therefore, it is believed that this phenomenon can generate significant irreproducibility in the performance of the photovoltaic cells (or solar cells) thus obtained.

Kim et al, in “Journal of Materials Chemistry A” (2019), Vol. 7, pg. 20832-20839, report a process for the fabrication of perovskite-based solar cells with the following layout: TiO₂/FAₓMA₁₋ₓPbI₃-PDMS/spiro-OMeTAD/Au. The process involves depositing of a photoactive layer of perovskite by spin coating starting from solutions containing PbI₂, MAI, FAI and DMSO (in a molar ratio of 1:0.85:0.15:1) in DMF. During the spin coating step, 0.3 ml of a toluene solution containing various amounts by weight of polydimethylsiloxane (PDMS) are added to the substrate. By operating under the most favorable conditions (i.e. PDMS=0.03% by weight in toluene) perovskite-based solar cells are obtained having a power conversion efficiency (PCE) equal to 15.44%, thanks to the obtainment of perovskite crystals with a more regular shape and with a narrower distribution of their dimensions. However, it is believed that the above process is not suitable for use in the scaling up phase for the construction of large area photovoltaic cells (or solar cells), as it provides for an annealing step at 500° C. for the formation of the TiO₂ layer and a two-step process, with the addition of a non-solvent, for the formation of the perovskite photoactive layer. Furthermore, since with the process described above it is not possible to determine the amount of PDMS which is effectively incorporated in the perovskite photoactive layer, said process probably does not guarantee good reproducibility of the results.

Liu G. et al, in “ACS Applied Materials & Interfaces” (2020), Vol. 12, pg. 14049, report a process for the fabrication of perovskite-based solar cells with the following layout: PEDOT:PSS/FASnI₃-EVA/PCBM-BTP/Ag. The process involves the formation of the perovskite photoactive layer by depositing DMSO/DMF solutions (1/4, v/v) containing equimolar amounts of SnI₂ and FAI via spin coating. During the spin coating step, solutions of chlorobenzene containing various percentages by weight of polyethylene vinyl acetate (EVA) are added to the substrate. Operating under the most favorable conditions (i.e. EVA=2 mg/ml in chlorobenzene), perovskite-based solar cells are obtained having a power conversion efficiency (PCE) equal to 7.72%, thanks to the obtainment of a better quality perovskite photoactive layer and to the increase in the size of the perovskite crystals. However, it is believed that the aforementioned process is not suitable for use in the scaling up phase for the construction of large area photovoltaic cells (or solar cells), as it involves a two-step process, with the addition of a non-solvent, for the formation of the perovskite photoactive layer. Furthermore, since with the process described above it is not possible to determine the amount of EVA which is actually incorporated in the perovskite photoactive layer, said process probably does not guarantee good reproducibility of the results.

Xue Q. et al., in “RSC Advances” (2015), Vol. 7, pg. 775-783, report a process for the fabrication of perovskite-based solar cells with the following layout: PEDOT:PSS/MAPbI₃-PEOXA/PCBM/Al. The above reported process, both as regards the manufacturing of the perovskite-based solar cells and as regards the manufacturing of the photoactive layer, is not reported in detail: however, the authors declare that the results obtained strongly depend on the type of solvent used to dissolve the perovskite precursors and the amount of used poly(2-ethyl-2-oxazoline) (PEOXA). By operating under the most favorable conditions (i.e. γ-butyrolactone (GBL) as solvent and 1.5% by weight of PEOXA), perovskite-based solar cells are obtained having a power conversion efficiency (PCE) equal to 6.16% thanks to a better control of the crystallization process and of the morphology of the perovskite photoactive layer.

Guo Y. et al., in “Advanced Energy Materials” (2016), Vol. 6, 1502317, report a process for the fabrication of perovskite-based solar cells with the following layout: PEDOT:PSS/MAPbIₓCl₃₋ₓ-PVP/PCBM-PEIE/Ag. The process involves the preparation of the perovskite photoactive layer by depositing a DMF solution via spin coating containing the perovskite precursors: MAI, PbI₂ and PbCl₂ (in a molar ratio of 4:1:1) and variable amounts (0% by weight—6% by weight) of polyvinylpyrrolidone (PVP). By operating under the most favorable conditions (i.e. PVP at 3% by weight), perovskite-based solar cells are obtained having a power conversion efficiency (PCE) equal to 7.91% also obtaining a significant improvement as regards the thermal stability of the perovskite photoactive layer thanks to an improvement in the dimensions and morphology of the perovskite crystals.

### SUMMARY

From the above, it is evident the importance of finding other polymers capable of being used as additives in the perovskite photoactive layer which allow to obtain perovskite-based photovoltaic cells (or solar cells) (Perovskite Solar Cells—PSCs) capable of having a good power conversion efficiency (PCE), as well as a process for their construction suitable for being used in the scaling up phase for the construction of photovoltaic cells (or solar cells) of large area.

The Applicant therefore faced the problem of finding a perovskite-based photovoltaic cell (or solar cell) capable of having a good power conversion efficiency (PCE), as well as a process for its construction suitable for use in the scaling up phase for the construction of photovoltaic (or solar cell) of large area.

The Applicant has now found a perovskite-based photovoltaic cell (or solar cell) wherein the perovskite photoactive layer comprises at least one partially neutralized polyacrylic acid in an amount greater than or equal to 3% by weight, preferably comprised between 4% by weight and 15% by weight, more preferably comprised between 4.5% by weight and 12% by weight, with respect to the total weight of the perovskite precursors, capable of having a good power conversion efficiency (PCE) (i.e. PCE>10%), as well as a process for its construction which provides for the deposition of the perovskite photoactive layer in a single step without the use of a non-solvent and deposition temperatures of the various layers below 120° C. Said process is, therefore, suitable for use in the scaling up phase for the construction of photovoltaic cells (or solar cells) of large area. Furthermore, said perovskite-based photovoltaic cell (or solar cell) is able to maintain good photoelectric properties, i.e. good values of FF (Fill Factor), Voc (Open Circuit Voltage), Jsc (short-circuit photocurrent). Said perovskite-based photovoltaic cell (or solar cell) can be advantageously used in various applications that require the production of electricity through the exploitation of light energy, in particular of solar radiation energy such as, for example: architecturally integrated photovoltaic systems (Building Integrated Photo Voltaic—BIPV); photovoltaic windows; greenhouses; photo-bioreactors; noise barriers; lighting engineering; design; advertisement; automobile industry. Furthermore, said perovskite-based photovoltaic cell (or solar cell) can be used both in stand-alone mode and in modular systems.

The present disclosure therefore provides a perovskite-based photovoltaic cell (or solar cell) wherein the photoactive layer of perovskite comprises at least one partially neutralized polyacrylic acid in an amount greater than or equal to 3% by weight, preferably comprised between 4% by weight and 15% by weight, more preferably comprised between 4.5% by weight and 12% by weight, with respect to the total weight of perovskite precursors.

### DETAILED DESCRIPTION OF THE DISCLOSURE

For the purpose of the present description and of the claims that follow, the definitions of the numerical ranges always include the extremes unless otherwise specified.

For the purposes of the present description and of the claims that follow, the term “comprising” also includes the terms “consisting essentially of” or “consisting of”.

According to a preferred embodiment of the present disclosure, said perovskite can be selected, for example, from organometallic trihalides having the general formula ABX₃ wherein:
A represents a monovalent organic cation such as, for example, methylammonium (CH₃NH₃⁺), formamidinium [CH(NH₂)₂⁺], n-butylammonium (C₄H₁₂NH₃⁺), tetra-butylammonium (C₁₆H₃₆N⁺), or mixtures thereof; or A represents a monovalent inorganic cation such as, for example, cesium (Cs⁺), rubidium (Rb⁺), potassium (K⁺), lithium (Li⁺), sodium (Na⁺), copper (Cu⁺), silver (Ag⁺), or mixtures thereof; or mixtures thereof;
B represents a divalent metal cation such as, for example, lead (Pb²⁺), tin (Sn²⁺), or mixtures thereof;
X represents a halide anion such as, for example, iodine (I⁻), chlorine (Cl⁻), bromine (Br⁻), or mixtures thereof.

According to a further preferred embodiment of the present disclosure, said perovskite can be selected, for example from: methylammonium lead iodide (CH₃NH₃PbI₃), methylammonium lead bromide (CH₃NH₃PbBr₃), methylammonium lead chloride (CH₃NH₃PbCl₃), methylammonium lead iodide bromide (CH₃NH₃PbIₓBr₃₋ₓ), methylammonium lead iodide chloride (CH₃NH₃PbIₓCl₃₋ₓ), formamidinium lead iodide [CH(NH₂)₂PbI₃], formamidinium lead bromide [CH(NH₂)₂PbBr₃], formamidinium lead chloride [CH(NH₂)₂PbCl₃], formamidinium lead iodide bromide [CH(NH₂)₂PbIₓBr₃₋ₓ], formamidinium lead iodide chloride [CH(NH₂)₂PbIₓCl₃₋ₓ], methylammonium formamidinium lead iodide [(CH₃NH₃)ₓ(CH(NH₂)₂)₁₋ₓPbI₃], methylammonium formamidinium lead bromide [(CH₃NH₃)x(CH(NH₂)₂)₁₋ₓPbBr₃], methylammonium formamidinium lead chloride [(CH₃NH₃)ₓ(CH(NH₂)₂)₁₋ₓPbCl₃], methylammonium formamidinium lead iodide chloride [(CH₃NH₃)ₓ(CH(NH₂)₂)₁₋ₓPbI_{3-y}Cl_{y}], methylammonium formamidinium lead iodide bromide [(CH₃NH₃)(CH(NH₂)₂)₁₋ₓPbI_{3-y}Br_{y}], n-butylammonium lead iodide (C₄H₁₂NH₃PbI₃), tetra-butylammonium lead iodide (C₁₆H₃₆NPbI₃), n-butylammonium lead bromide (C₄H₁₂NH₃PbBr₃), tetra-butylammonium lead bromide (C₁₆H₃₆NPbBr₃), cesium lead iodide (CsPbI₃), rubidium lead iodide (RbPbI₃), potassium lead iodide (KPbI₃), cesium methylammonium lead iodide [Csₓ(CH₃NH₃)₁₋ₓPbI₃], potassium methylammonium lead iodide [Kₓ(CH₃NH₃)₁₋ₓPbI₃], cesium methylammonium lead iodide chloride [Csₓ(CH₃NH₃)₁₋ₓPbI_{3-y}Cl_{y}], cesium formamidinium lead iodide [Csₓ(CH(NH₂)₂)₁₋ₓPbI₃], cesium formamidinium lead bromide [Csₓ(CH(NH₂)₂)₁₋ₓPbBr₃], cesium formamidinium lead iodide chloride [Csₓ(CH(NH₂)₂)₁₋ₓPbI_{3-y}Cl_{y}], methylammonium tin iodide (CH₃NH₃SnI₃), methylammonium tin bromide (CH₃NH₃SnBr₃), methylammonium tin iodide bromide (CH₃NH₃SnIₓBr₃₋ₓ), formamidinium tin iodide [CH(NH₂)₂SnI₃], formamidinium tin iodide bromide [CH(NH₂)₂SnIₓBr₃₋ₓ], n-butylammonium tin iodide (C₄H₁₂NH₃SnI₃), tetra-butylammonium tin iodide (C₁₆H₃₆NSnI₃), n-butylammonium tin bromide (C₄H₁₂NH₃SnBr₃), tetra-butylammonium tin bromide (C₁₆H₃₆NSnBr₃), methylammonium tin lead iodide (CH₃NH₃SnₓPb₁₋ₓI₃), formamidinium tin lead iodide [CH(NH₂)₂SnPb₁₋ₓI₃], or mixtures thereof. Methylammonium lead iodide (CH₃NH₃PbI₃), formamidinium lead iodide [CH(NH₂)₂PbI₃], methylammonium formamidinium lead iodide chloride [(CH₃NH₃)ₓ(CH(NH₂)₂)₁₋ₓPbI_{3-y}Cl_{y}], cesium methylammonium lead iodide chloride [Csₓ(CH₃NH₃)₁₋ₓPbI_{3-y}Cl_{y}], cesium formamidinium lead iodide chloride [Csₓ(CH(NH₂)₂)₁₋ₓPbI_{3-y}Cl_{y}], are preferred. Methylammonium lead iodide (CH₃NH₃PbI₃) is even more preferred.

According to a preferred embodiment of the present disclosure, said partially neutralized polyacrylic acid has the general formula (I):

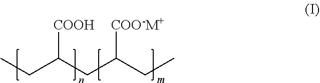

wherein:
n and m are integers and:
   the sum n+m is comprised between 10 and 60000, preferably comprised between 15 and 15000, more preferably comprised between 20 and 6000;
   the ratio n:m is comprised between 99:1 and 1:99, preferably comprised between 98:2 and 20:80, more preferably comprised between 95:5 and 50:50;
M⁺ represents a monovalent metal cation selected from alkali metals such as, for example, lithium (Li⁺), sodium (Na⁺), potassium (K⁺), rubidium (Rb⁺), cesium (Cs⁺), preferably lithium (Li⁺), potassium (K⁺), rubidium (Rb⁺), cesium (Cs⁺), more preferably potassium (K⁺), cesium (Cs⁺); or from other monovalent metals such as, for example, copper (Cu⁺), silver (Ag⁺), gold (Au⁺), mercury (Hg⁺), thallium (Tl⁺), preferably copper (Cu⁺), silver (Ag⁺);
or M represents a monovalent cation having general formula (II):

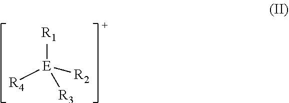

wherein:
   E represents a nitrogen atom, a phosphorus atom, preferably a nitrogen atom;
   R₁, R₂, R₃, and R₄, identical to or different from each other, represent a hydrogen atom; or are selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups;
   or R₁ and R₂, and/or R₂ and R₃, and/or R₃ and R₄, and/or R₄ and R₁, can possibly be bonded together so as to form, together with the other atoms to which they are bonded, a saturated, unsaturated, or aromatic cycle containing from 2 to 12 carbon atoms, optionally substituted with C₁-C₂₀, preferably C₁-C₁₂, linear or branched, saturated or unsaturated, optionally containing heteroatoms alkyl groups, optionally substituted aryl groups, optionally substituted heteroaryl groups, optionally substituted cycloalkyl groups, optionally substituted heterocyclic groups, trialkyl- or triaryl-silyl groups, dialkyl- or diaryl-amino groups, dialkyl- or diaryl-phosphinic groups, C₁-C₂₀, preferably C₂-C₁₀, linear or branched, saturated or unsaturated alkoxy groups, optionally substituted aryloxy groups, optionally substituted thioalkoxy or thioaryloxy groups, cyano groups, said cycle optionally containing heteroatoms such as, for example, oxygen, sulfur, nitrogen, silicon, phosphorus, selenium, preferably oxygen, nitrogen;
or M⁺ represents a monovalent cation having general formula (III):

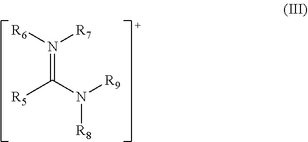

wherein:
   R₅ represents a hydrogen atom; or represents a halogen atom such as, for example, fluorine, chlorine bromine, iodine, preferably fluorine, chlorine; or is selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups; preferably R₅ is hydrogen or methyl;
   R₆, R₇, R₈ and R₉, identical to or different from each other, represent a hydrogen atom; or are selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups;
   or R₇ and R₈, and/or R₉ and R₁₀ can possibly be bonded together so as to form, together with the other atoms to which they are bonded a saturated, unsaturated, or aromatic cycle containing from 2 to 12 carbon atoms, optionally substituted with linear or branched C₁-C₂₀, saturated or unsaturated, optionally containing heteroatoms alkyl groups, optionally substituted aryl groups, optionally substituted heteroaryl groups, optionally substituted cycloalkyl groups, optionally substituted heterocyclic groups, trialkyl- or triaryl-silyl groups, dialkyl- or diaryl-amino groups, dialkyl- or diaryl-phosphinic groups, C₁-C₂₀, preferably C₂-C₁₀, linear or branched, saturated or unsaturated alkoxy groups, optionally substituted aryloxy groups, optionally substituted thioalkoxy or thioaryloxy groups, cyano groups, said cycle optionally containing heteroatoms such as, for example, oxygen, sulfur, nitrogen, silicon, phosphorus, selenium, preferably oxygen, nitrogen; preferably R₆, R₇, R₈ and R₉ represent a hydrogen atom.

For the purposes of the present description and of the claims that follow, the term “C₁-C₂₀ alkyl groups” indicates linear or branched, saturated or unsaturated alkyl groups having from 1 to 20 carbon atoms. Specific examples of C₁-C₂₀ alkyl groups are: methyl, ethyl, n-propyl, iso-propyl, n-butyl, iso-butyl, tert-butyl, pentyl, hexyl, heptyl, octyl, 2-ethylheptyl, 2-ethylhexyl, 2-butenyl, 2-pentenyl, 2-ethyl-3-hexenyl, 3-octenyl, 1-methyl-4-hexenyl, 2-butyl-3-hexenyl.

For the purposes of the present description and of the claims that follow, the term “C₁-C₂₀ alkyl groups optionally containing heteroatoms” indicates linear or branched, saturated or unsaturated alkyl groups having from 1 to 20 carbon atoms, wherein at least one of the hydrogen atoms is substituted with a heteroatom selected from: halogens such as, for example, fluorine, chlorine, bromine, preferably fluorine; nitrogen; sulfur; oxygen. Specific examples of C₁-C₂₀ alkyl groups optionally containing heteroatoms are: fluoromethyl, difluoromethyl, trifluoromethyl, trichloromethyl, 2,2,2-trifluoroethyl, 2,2,2-trichloroethyl, 2,2,3,3-tetrafluoropropyl, 2,2,3,3,3-pentafluoropropyl, perfluoropentyl, perfluorooctyl, perfluorodecyl, ethyl-2-methoxy, propyl-3-ethoxy, butyl-2-thiomethoxy, hexyl-4-amino, hexyl-3-N,N′-dimethylamino, methyl-N,N′-dioctylamino, 2-methyl-hexyl-4-amino.

For the purposes of the present description and of the claims that follow, the term “aryl groups” indicates aromatic carbocyclic groups containing from 6 to 60 carbon atoms. Said aryl groups can optionally be substituted with one or more groups, identical to or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxyl groups; cyano groups; amino groups; C₁-C₁₂ mono- or di-alkylamino groups; nitro groups. Specific examples of aryl groups are: phenyl, methylphenyl, trimethylphenyl, methoxyphenyl, hydroxyphenyl, phenyloxyphenyl, fluorophenyl, pentafluorophenyl, chlorophenyl, bromophenyl, nitrophenyl, dimethylaminophenyl, naphthyl, phenylnaphthyl, phenanthrene, anthracene.

For the purposes of the present description and of the claims that follow, the term “heteroaryl groups” means aromatic, penta- or hexa-atomic heterocyclic groups, also benzocondensate or heterobicyclic, containing from 4 to 60 carbon atoms and from 1 to 4 heteroatoms selected from nitrogen, oxygen, sulfur, silicon, selenium, phosphorus. Said heteroaryl groups can optionally be substituted with one or more groups, identical to or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxyl groups; cyano groups; amino groups; C₁-C₁₂ mono- or di-alkylamino groups; nitro groups. Specific examples of heteroaryl groups are: pyridine, methylpyridine, methoxypyridine, phenylpyridine, fluoropyridine, pyrimidine, pyridazine, pyrazine, triazine, tetrazine, quinoline, quinoxaline, quinazoline, furan, thiophene, hexylthiophene, bromothiophene, dibromothiophene, pyrrole, oxazole, thiazole, isooxazole, isothiazole, oxadiazole, thiadiazole, pyrazole, imidazole, triazole, tetrazole, indole, benzofuran, benzothiophene, benzooxazole, benzothiazole, benzooxadiazole, benzothiadiazole, benzopyrazole, benzimidazole, benzotriazole, triazolopyridine, triazolopyrimidine, coumarin.

For the purpose of the present description and of the claims that follow, the term “cycloalkyl groups” means cycloalkyl groups having from 3 to 60 carbon atoms. Said cycloalkyl groups can optionally be substituted with one or more groups, identical to or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxyl groups; cyano groups; amino groups; C₁-C₁₂ mono- or di-alkylamino groups; nitro groups. Specific examples of cycloalkyl groups are: cyclopropyl, 2,2-difluorocyclopropyl, cyclobutyl, cyclopentyl, cyclohexyl, methylcyclohexyl, methoxycyclohexyl, fluorocyclohexyl, phenylcyclohexyl, decalin, abiethyl.

For the purposes of the present description and of the claims that follow, the term “heterocyclic groups” indicates rings having from 3 to 12 atoms, saturated or unsaturated, containing at least one heteroatom selected from nitrogen, oxygen, sulphur, silicon, selenium, phosphorus, optionally condensed with other aromatic or non-aromatic rings. Said heterocyclic groups can optionally be substituted with one or more groups, identical to or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; polyethyleneoxyl groups; cyano groups; amino groups; C₁-C₁₂ mono- or di-alkylamino groups; nitro groups. Specific examples of heterocyclic groups are: pyrrolidine, methoxypyrrolidine, piperidine, fluoropiperidine, methylpiperidine, dihydropyridine, piperazine, morpholine, thiazine, indoline, phenylindoline, 2-ketoazetidine, diketopiperazine, tetrahydrofuran, tetrahydrothiophene.

For the purposes of the present description and of the claims that follow, the term “cycle” indicates a system containing a ring containing from 1 to 12 carbon atoms, optionally containing heteroatoms selected from nitrogen, oxygen, sulphur, silicon, selenium, phosphorus. Specific examples of cycles are: toluene, benzonitrile, cycloheptatriene, cyclooctadiene, pyridine, piperidine, tetrahydrofuran, thiadiazole, pyrrole, thiophene, selenophene, tert-butylpyridine.

For the purposes of the present description and of the claims that follow, the term “trialkyl- or triaryl-silyl groups” indicates groups comprising a silicon atom to which are bonded three C₁-C₁₂ alkyl groups, or three C₆-C₂₄ aryl groups, or a combination thereof. Specific examples of trialkyl- or triaryl-silyl groups are: trimethylsilane, triethylsilane, trihexylsilane, tridodecylsilane, dimethyldodecylsilane, triphenylsilane, methyldiphenylsilane, dimethylnaphthylsilane.

For the purposes of the present description and of the claims that follow, the term “dialkyl- or diaryl-amino groups” indicates groups comprising a nitrogen atom to which two C₁-C₁₂ alkyl groups, or two C₆-C₂₄ aryl groups, or a combination thereof. Specific examples of dialkyl- or diaryl-amino groups are: dimethylamine, diethylamine, dibutylamine, diisobutylamine, diphenylamine, methylphenylamine, dibenzylamine, ditolylamine, dinaphthylamine.

For the purposes of the present description and of the claims that follow, the term “dialkyl- or diaryl-phosphine groups” indicates groups comprising a phosphorus atom to which are bonded two C₁-C₁₂ alkyl groups, or two C₆-C₂₄ aryl groups, or a combination thereof. Specific examples of dialkyl- or diaryl-phosphine groups are: dimethylphosphine, diethylphosphine, dibutylphosphine, diphenylphosphine, methylphenylphosphine, dinaphthylphosphine.

For the purposes of the present description and of the claims that follow, the term “C₁-C₂₀ alkoxy groups” indicates groups comprising an oxygen atom to which is bonded a linear or branched C₁-C₂₀ alkyl group. Specific examples of C₁-C₂₀ alkoxy groups are: methoxy, ethoxy, n-propoxy, iso-propoxy, n-butoxy, iso-butoxy, tert-butoxy, pentoxy, hexyloxy, heptyloxy, octyloxy, nonyloxy, decyloxy, dodecyloxy.

For the purposes of the present description and of the claims that follow, the term “aryloxy groups” indicates groups comprising an oxygen atom to which is bonded a C₆-C₂₄ aryl group. Said aryloxy groups can optionally be substituted with one or more groups, identical to or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; cyano groups; amino groups; C₁-C₁₂ mono- or di-alkylamino groups; nitro groups. Specific examples of aryloxy groups are: phenoxy, para-methylphenoxy, para-fluorophenoxy, ortho-butylphenoxy, naphthyloxy, anthracenoxy.

For the purposes of the present description and of the claims that follow, the term “thioalkoxy or thioaryloxy groups” indicates groups comprising a sulfur atom to which is bonded a C₁-C₁₂ alkoxy group or a C₆-C₂₄ aryloxy group. Said thioalkoxy or thioaryloxy groups can optionally be substituted with one or more groups, identical to or different from each other, selected from: halogen atoms such as, for example, fluorine, chlorine, bromine, preferably fluorine; hydroxyl groups; C₁-C₁₂ alkyl groups; C₁-C₁₂ alkoxy groups; C₁-C₁₂ thioalkoxy groups; C₃-C₂₄ tri-alkylsilyl groups; cyano groups; amino groups; C₁-C₁₂ mono- or di-alkylamino groups; nitro groups. Specific examples of thioalkoxy or thioaryloxy groups are: thiomethoxy, thioethoxy, thiopropoxy, thiobutoxy, thio-iso-butoxy, 2-ethylthiohexyl, thiophenoxy, para-methylthiophenoxy, para-fluorothiophenoxy, ortho-butylthiophenoxy, naphthylthiooxyl, anthracenylthiooxyl.

According to a preferred embodiment of the present disclosure, in said partially neutralized polyacrylic acid free carboxyl groups are present in an amount comprised between 1% and 99%, preferably comprised between 20% and 98%, more preferably comprised between 50% and 96%, with respect to the total amount of carboxyl groups present in said polyacrylic acid.

The above partially neutralized polyacrylic acid can be obtained according to processes known in the art. For example, the starting polyacrylic acid can be made to react with a carbonate or bicarbonate of an alkali metal selected from those listed above, in the presence of water, for the time necessary to obtain the desired amount of neutralized carboxyl groups: further details to the preparation of the partially neutralized polyacrylic acid are given in the following examples.

According to a preferred embodiment of the present disclosure, the starting polyacrylic acid (i.e. not partially neutralized) can have a weight average molecular weight (M_{w}) comprised between 700 Da and 4000000 Da, preferably comprised between 1000 Da and 1000000 Da, more preferably comprised between 1500 Da and 400000 Da.

According to a preferred embodiment of the present disclosure, said perovskite-based photovoltaic cell (or solar cell) comprises:
a glass substrate coated with a layer of transparent and conductive oxide (Transparent Conductive Oxide—TCO), generally fluorine-doped tin oxide (SnO₂:F) (Fluorine-doped Tin Oxide—FTO), or indium tin oxide (Indium Tin Oxide—ITO) which constitutes the anode;
a layer based on a hole transport material (Hole Transport Layer—HTL), preferably a layer of poly[bis(4-butylphenyl)-bisphenylbenzidine] (Poly-TPD);
optionally a layer based on a material useful for improving wettability, preferably a layer of poly[9,9-bis(3′-(N,N-dimethyl)-N-ethylammonium-propyl-2,7-fluorene)-alt-2,7-(9,9-dioctylfluorene)]diiodide (PFN-I), or a layer of poly[9,9-bis(3′-(N,N-dimethyl)-N-ethylammonium-propyl-2,7-fluorene)-alt-2,7-(9,9-dioctylfluorene)] (PFN);
a photoactive layer comprising at least one perovskite, preferably methylammonium lead iodide (CH₃NH₃PbI₃) [methylammonium lead iodide (CH₃NH₃PbI₃) is the most used structure as it has a high absorption coefficient throughout the UV and visible spectrum, a band-gap equal to 1.57 eV, close to the optimal value to maximize the conversion efficiency and a considerable diffusion distance of the electrons and electronic holes (or holes) (over 100 nm)], and at least one partially neutralized polyacrylic acid, preferably a partially neutralized polyacrylic acid with cesium or potassium, having an amount of free carboxyl groups comprised between 60% and 95%;
a layer based on an electron transport material (Electron Transport Layer—ETL), preferably a layer of methyl ester of [6,6]-phenyl-C₆₁-butyric acid (PC₆₁BM);
optionally, a layer based on a hole blocking material (Hole Blocking Layer—HBL), preferably a layer of 2,9-dimethyl-4,7-diphenyl-1,10-phenanthroline (Batocuproin—BCP) or polyethylenimine ethoxylated (PEIE);
a metallic contact known as back contact which constitutes the cathode, preferably a layer of gold, silver or metallic aluminium.

According to a preferred embodiment of the present disclosure, the electrical energy generated by said at least one perovskite-based photovoltaic cell (or solar cell) can be transported using a wiring system which is connected with said perovskite-based photovoltaic cell (or solar cell).

As stated above, the present disclosure provides a process for the preparation of said perovskite-based photovoltaic cell (or solar cell).

Consequently, the present disclosure provides a process for preparing a perovskite-based photovoltaic cell (or solar cell) comprising the following steps:
(a) preparing a glass substrate coated with a transparent and conductive oxide layer (Transparent Conductive Oxide—TCO) (anode);
(b) depositing a layer based on a hole transport material (Hole Transport Layer HTL) on the substrate obtained in said step (a);
(c) optionally, depositing on the layer based on a hole transport material (Hole Transport Layer—HTL) obtained in said step (b) a layer based on a material useful for improving wettability;
(d) preparing a mixture comprising perovskite precursors and at least one partially neutralized polyacrylic acid, said partially neutralized polyacrylic acid being present in said mixture in an amount greater than or equal to 3% by weight, preferably comprised between 4% by weight and 15% by weight, more preferably comprised between 4.5% by weight and 12% by weight, with respect to the total weight of the perovskite precursors;
(e) depositing the mixture obtained in said step (d) on the layer based on a hole transport material (Hole Transport Layer—HTL) obtained in said step (b), or on the layer based on a material useful for improving wettability obtained in said step (c), obtaining a photoactive layer;
(f) depositing a layer based on an electron transport material (Electron Transport Layer—ETL), on the photoactive layer obtained in said step (e);
(g) optionally, depositing on the layer based on an electron transport material (Electron Transport Layer—ETL) obtained in said step (f), a layer based on a hole blocking material (Hole Blocking Layer—HBL);
(h) depositing a metallic contact known as back contact which constitutes the cathode, on the layer based on an electron transport material (ETL) obtained in said step (f), or on the layer based of a hole blocking material (Hole Blocking Layer—HBL) obtained in said step (g);
   wherein said steps (b), (c), (e), (f) and (g), are carried out at a temperature lower than 120° C., preferably comprised between 20° C. and 115° C.

For the purposes of the above process, said transparent and conductive oxide (Transparent Conductive Oxide—TCO), said layer based on a hole transport material (Hole Transport Layer—HTL), said layer based on an electron transport material (Electron Transport Layer—ETL), said layer based on a material useful for improving wettability, said layer based on a hole blocking material (Hole Blocking Layer—HBL) and said metal contact known as back contact, are selected from those listed above.

For the purpose of the aforementioned process, said mixture comprising perovskite precursors and at least one polyacrylic acid, comprises:
at least one halide selected from the halides of the monovalent organic cations or of the monovalent inorganic cations listed above, preferably iodides, chlorides, bromides, more preferably iodides [for example, methylammonium iodide (MAI) (CH₃NH₃I)], and at least a halide selected from the halides of the above mentioned divalent metal cations, preferably iodides, chlorides, bromides, more preferably iodides [for example, lead iodide (PbI₂)] as perovskite precursors;
at least one partially neutralized polyacrylic acid, preferably a partially neutralized polyacrylic acid with cesium or potassium, having an amount of free carboxyl groups comprised between 60% and 95%.

For the purpose of the above process, said steps (b), (c), (e), (f) and (g), can be carried out according to deposition techniques known in the art such as, for example, spin-coating, spray-coating, ink-jet printing, slot die coating, gravure printing, screen printing.

For the purpose of the above process, said step (h) can be carried out according to techniques known in the art such as, for example, evaporation, sputtering, electron beam assisted deposition, sputtering, spin coating, gravure printing, flexographic printing, slot die coating.

As mentioned above said perovskite-based photovoltaic cell (or solar cell) can be advantageously used in various applications that require the production of electricity through the exploitation of light energy, in particular of solar radiation energy such as, for example: architecturally integrated photovoltaic systems (Building Integrated Photo Voltaic—BIPV); photovoltaic windows; greenhouses; photo-bioreactors; noise barriers; lighting engineering; design; advertising; automobile industry. In addition, said perovskite-based photovoltaic cell (or solar cell) can be used both in stand-alone mode and in modular systems.

Consequently, it is a further advantage of the present disclosure, for the use of said perovskite-based photovoltaic cell (or solar cell) in: architecturally integrated photovoltaic systems (Building Integrated Photo Voltaic—BIPV); photovoltaic windows; greenhouses; photo-bioreactors; noise barriers; lighting engineering; design; advertising; automobile industry.

As stated above, another advantage of the present disclosure is to provide a composition comprising at least one perovskite and at least one partially neutralized polyacrylic acid.

Consequently, the present disclosure provides a composition comprising at least one perovskite and at least one partially neutralized polyacrylic acid in an amount greater than or equal to 3% by weight, preferably comprised between 4% by weight and 15% by weight, more preferably comprised between 4.5% by weight and 12% by weight, with respect to the total weight of the perovskite precursors.

Said at least one perovskite and said at least one partially neutralized polyacrylic acid can be selected from those reported above.

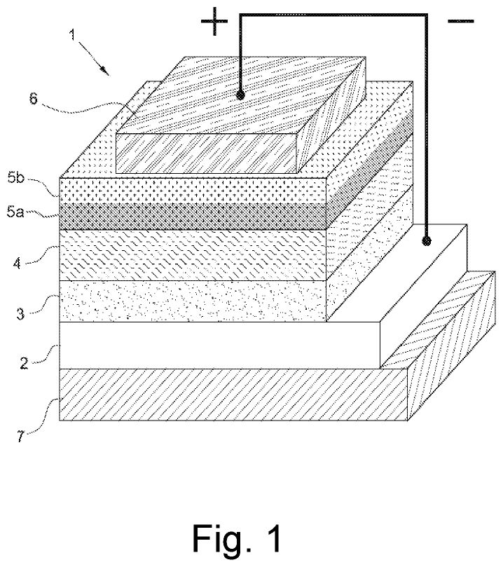

The present disclosure will now be illustrated in greater detail through an embodiment with reference to FIG. 1 reported below.

In particular, FIG. 1 represents a cross-sectional view of a perovskite-based photovoltaic cell (or solar cell) (1) comprising the following layers: a glass substrate (7) coated with a transparent and conductive oxide layer (Transparent Conductive Oxide—TCO) (anode) [e.g., indium tin oxide (ITO) or fluorine-doped tin oxide (SnO₂:F) (Fluorine-doped Tin Oxide—FTO)] (2); a layer based on a hole transport material (Hole Transport Layer—HTL) [e.g., poly[bis(4-butylphenyl)-bisphenylbenzidine] (Poly-TPD)] (3); optionally a layer based on a material useful for improving wettability, [e.g., poly[9,9-bis(3′-(N,N-dimethyl)-N-ethylammonium-propyl-2,7-fluorene)-alt-2,7-(9,9-dioctylfluorene)]di-iodide (PFN-I), or poly[9,9-bis(3′-(N,N-dimethyl)-N-ethylammonium-propyl-2,7-fluorene)-alt-2,7-(9,9-dioctylfluorene)] (PFN)](not shown in FIG. 1); a photoactive layer comprising at least one perovskite [e.g., methylammonium lead iodide (CH₃NH₃PbI₃) and at least one partially neutralized polyacrylic acid (e.g., a partially neutralized polyacrylic acid with cesium or potassium, having an amount of free carboxyl groups comprised between 60% and 95%) (4); a layer based on an electron transporting material (Electron Transport Layer—ETL) [e.g., methyl ester of [6,6]-phenyl-C₆₁-butyric acid (PC₆₁BM)] (5a); a layer based on a hole blocking material (Hole Blocking Layer—HBL) [e.g., 2,9-dimethyl-4,7-diphenyl-1,10-phenanthroline (Batocuproine-BCP) or ethoxylated polyethyleneimine (PEIE)] (5b); a metallic contact known as back contact which constitutes the cathode [e.g., a layer of gold, silver or metallic aluminum](6).

In order to better understand the present disclosure and to put it into practice, some illustrative and non-limiting examples of the same are given below.

In the following examples, for greater simplicity, the term solar cell is used, which is to be understood as having the same meaning as photovoltaic cell.

### Example 1

### Preparation of Polyacrylic Acid Partially Neutralized with Cesium (PACs5)

3.07 g of polyacrylic acid (42.6 mmoles of monomer units) (weight average molecular weight (M_{w})=1800 Da (Aldrich) were introduced into a 250 ml flask and dissolved in 75 ml of ultrapure water: the solution obtained was filtered using a millipore filter (porosity 45 m). 0.34 g of cesium carbonate (Cs₂CO₃) (2.08 mmoles of cesium) (Aldrich) dissolved in 20 ml of ultrapure water were added to the filtered solution. The reaction mixture was left, under stirring, at room temperature (25° C.), for 5 minutes, then it was heated to a temperature of 80° C. and maintained at said temperature, under stirring, for 2 hours, to facilitate the elimination of the formed carbon dioxide. The solution was left to cool at room temperature (25° C.), filtered again using a millipore filter (porosity 45 m) to eliminate any impurities and subsequently freeze-dried, obtaining 2.85 g of partially neutralized polyacrylic acid as a flaky white solid. The sample was analyzed by ICP-OES (Inductively Coupled Plasma-Optical Emission Spectrometry) operating as reported below and showed a cesium content equal to 8.3% which corresponds to about 5% of neutralized —COOH groups, i.e. transformed into —COO⁻Cs⁺.

### ICP-OES Analysis (Inductively Coupled Plasma-Optical Emission Spectrometry)

The samples to be analyzed were prepared by acid digestion.

For this purpose, 50 mg of partially neutralized polyacrylic acid obtained as described above was placed in a 200 ml flask to which 7.5 ml of nitric acid (65% by weight aqueous solution—Aldrich) and 2.5 ml of sulfuric acid (95% by weight aqueous solution—Aldrich) was added: the resulting mixture was heated to 120° C., maintained at said temperature for 20 hours and subsequently diluted with ultrapure water up to a volume of 50 ml. The solution thus obtained was subsequently diluted with a ratio of 1:10 (v/v) in nitric acid (HNO₃) (1% aqueous solution obtained by dilution of the 65% by weight aqueous solution—Aldrich) and subsequently analyzed by (Inductively Coupled Plasma—Optical Emission Spectrometry) (Spectro Genesis, Ametek).

The calibration curve was obtained using, for each of the two metals analyzed [i.e. cesium (Cs) and potassium (K)], five standard solutions with the following concentrations: 0.05 ppm, 0.10 ppm, 0.50 ppm, 1.00 ppm and 5.00 ppm. All the solutions were obtained by successive dilutions starting from two stock solutions of 1000 ppm for each metal. A solution of nitric acid (HNO₃) (1% aqueous solution obtained by dilution of the 65% by weight—Aldrich aqueous solution) was used as blank.

The operating conditions used were the following:
plasma gas flow: 0.5 L/min;
RF power: 1400 W;
measured wavelength: for the analysis of cesium (Cs) 455 nm, for the analysis of potassium (K) 766 nm.

Limits of Detection (LOD) were calculated using the background equivalent concentration (BEC) and the signal to background ratio (SBR), and turned out to be LOD (K)=0.001 mg/L, LOD (Cs)=0.003 mg/L.

### Example 2

### Preparation of Polyacrylic Acid Partially Neutralized with Cesium (PACs10)

Polyacrylic acid partially neutralized with cesium (PACs10) was prepared operating as described in Example 1 with the only difference deriving from the use of a different amount of cesium carbonate (Cs₂CO₃).

For this purpose, 3.07 g of polyacrylic acid (42.6 mmol of monomer units) (weight average molecular weight (M_{w})=1800 Da (Aldrich) were reacted with 0.62 g of cesium carbonate (Cs₂CO₃) (4.16 mmoles of cesium) (Aldrich), obtaining 2.98 g of partially neutralized polyacrylic acid which is in the form of a flaky white solid. The sample was analyzed by means of ICP-OES (Inductively Coupled Plasma—Optical Emission Spectrometry) operating as described in Example 1 and showed a cesium content equal to 15.4% which corresponds to about 10% of neutralized —COOH groups, i.e. transformed into —COO⁻Cs⁺.

### Example 3

### Preparation of Polyacrylic Acid Partially Neutralized with Cesium (PACs20)

Polyacrylic acid partially neutralized with cesium (PACs20) was prepared operating as described in Example 1 with the only difference deriving from the use of a different amount of cesium carbonate (Cs₂CO₃).

For this purpose, 3.07 g of polyacrylic acid (42.6 mmol of monomer units) (weight average molecular weight (M_{W})=1800 Da (Aldrich) were reacted with 1.36 g of cesium carbonate (Cs₂CO₃) (8.32 mmoles of cesium) (Aldrich), obtaining 3.22 g of partially neutralized polyacrylic acid which appears in the form of a flaky white solid. The sample was analyzed by means of ICP-OES (Inductively Coupled Plasma—Optical Emission Spectrometry) operating as described in Example 1 and showed a cesium content equal to 26.7% which corresponds to about 20% of neutralized —COOH groups, i.e. transformed into —COO⁻Cs⁺.

### Example 4

### Preparation of Polyacrylic Acid Partially Neutralized with Cesium (PACs40)

Polyacrylic acid partially neutralized with cesium (PACs40) was prepared operating as described in Example 1 with the only difference deriving from the use of a different amount of cesium carbonate (Cs₂CO₃).

For this purpose, 3.07 g of polyacrylic acid (42.6 mmol of monomer units) (weight average molecular weight (M_{w})=1800 Da (Aldrich) were reacted with 2.72 g of cesium carbonate (Cs₂CO₃) (16.6 mmoles of cesium) (Aldrich), obtaining 3.95 g of partially neutralized polyacrylic acid which appears in the form of a flaky white solid. The sample was analyzed by means of ICP-OES (Inductively Coupled Plasma—Optical Emission Spectrometry) operating as described in Example 1 and showed a cesium content equal to 42.1% which corresponds to about 40% of neutralized —COOH groups, i.e. transformed into —COO⁻Cs⁺.

### Example 5

### Preparation of Polyacrylic Acid Partially Neutralized with Potassium (PAK5)

Polyacrylic acid partially neutralized with potassium (PAK5) was prepared operating as described in Example 1 with the only difference deriving from the use of different amounts of potassium carbonate (KHCO₃).

For this purpose, 3.07 g of polyacrylic acid (42.6 mmol of monomer units) (weight average molecular weight (M_{w})=1800 Da (Aldrich) were reacted with 0.21 g of potassium carbonate (KHCO₃) (2.09 mmoles of potassium) (Aldrich), obtaining 2.68 g of partially neutralized polyacrylic acid which is in the form of a flaky white solid. The sample was analyzed by means of ICP-OES (Inductively Coupled Plasma—Optical Emission Spectrometry) operating as described in Example 1 and showed a potassium content equal to 2.2% which corresponds to about 5% of neutralized —COOH groups, i.e. transformed into —COO⁻K⁺.

### Example 6

### Preparation of Polyacrylic Acid Partially Neutralized with Potassium (PAK10)

Polyacrylic acid partially neutralized with potassium (PAK10) was prepared operating as described in Example 1 with the only difference deriving from the use of different amounts of potassium carbonate (KHCO₃).

For this purpose, 3.07 g of polyacrylic acid (42.6 mmol of monomer units) (weight average molecular weight (M_{w})=1800 Da (Aldrich) were reacted with 0.42 g of potassium carbonate (KHCO₃) (4.19 mmoles of potassium) (Aldrich), obtaining 2.98 g of partially neutralized polyacrylic acid which appears in the form of a flaky white solid. The sample was analyzed by means of ICP-OES (Inductively Coupled Plasma—Optical Emission Spectrometry) operating as described in Example 1 and showed a potassium content equal to 5% which corresponds to about 10% of neutralized —COOH groups, i.e. transformed into —COO⁻K⁺.

### Example 7

### Preparation of Polyacrylic Acid Partially Neutralized with Potassium (PA K20)

Polyacrylic acid partially neutralized with cesium (PAK20) was prepared operating as described in Example 1 with the only difference deriving from the use of different amounts of potassium carbonate (KHCO₃).

For this purpose, 3.07 g of polyacrylic acid (42.6 mmol of monomer units) (weight average molecular weight (M_{w})=1800 Da (Aldrich) were reacted with 0.84 g of potassium carbonate (KHCO₃) (8.39 mmoles of potassium) (Aldrich), obtaining 2.68 g of partially neutralized polyacrylic acid which appears in the form of a flaky white solid. The sample was analyzed by means of ICP-OES (Inductively Coupled Plasma—Optical Emission Spectrometry) operating as described in Example 1 and showed a potassium content equal to 9.4% which corresponds to about 20% of neutralized —COOH groups, i.e. transformed into —COO⁻K⁺.

### Example 8

### Preparation of Polyacrylic Acid Partially Neutralized with Potassium (PAK30)

Polyacrylic acid partially neutralized with cesium (PAK30) was prepared operating as described in Example 1 with the only difference deriving from the use of different amounts of potassium carbonate (KHCO₃).

For this purpose, 3.07 g of polyacrylic acid (42.6 mmol of monomer units) (weight average molecular weight (M_{w})=1800 Da (Aldrich) were reacted with 1.26 g of potassium carbonate (KHCO₃) (12.59 mmoles of potassium) (Aldrich), obtaining 2.68 g of partially neutralized polyacrylic acid which is in the form of a flaky white solid. The sample was analyzed by means of ICP-OES (Inductively Coupled Plasma—Optical Emission Spectrometry) operating as described in Example 1 and showed a potassium content equal to 12.3% which corresponds to about 30% of neutralized —COOH groups, i.e. transformed into —COO⁻K⁺.

### Example 9

### Preparation of a Perovskite-Based Solar Cell

For this purpose, a perovskite-based solar cell was prepared on a glass substrate coated with ITO Indium Tin Oxide (Kintec KT18086-1) and patterned (dimensions 15×15×1 mm; resistance surface equal to 12 Ω/cm²) previously subjected to a cleaning procedure consisting of manual cleaning, rubbing with a lint-free cloth soaked in a detergent diluted with deionized water. The substrate was then rinsed with deionized water. Subsequently, the substrate was thoroughly cleaned by the following sequential methods: ultrasonic baths in (i) deionized water plus detergent (followed by manual drying with a lint-free cloth); (ii) distilled water [followed by manual drying with a lint-free cloth]; (iii) acetone (Aldrich) and (iv) iso-propanol (Aldrich) in sequence. In particular, the substrate was arranged in a beaker containing the solvent, placed in an ultrasonic bath, maintained at 40° C., for a treatment of 10 minutes. After treatments (iii) and (iv), the substrate was dried with a flow of compressed nitrogen.

Subsequently, the glass/ITO was further cleaned by treatment in an ozone device (UV Ozone Cleaning System EXPO3—Astel), immediately before proceeding to the next step.

The thus treated substrate was ready for the deposition of the layer based on a hole transport material (Hole Transport Layer—HTL). For this purpose, a solution of poly[bis(4-butylphenyl)bisphenylbenzidine (Poly-TPD) (Aldrich) in chlorobenzene (purity 99.5%—Aldrich) at a concentration equal to 1.5 mg/ml, was deposited, by spin coating operating at a rotation speed of 4000 rpm (acceleration equal to 500 rpm/s), for 60 seconds: everything was subjected to heat treatment (annealing), at 110° C., for 30 minutes. The thickness of the layer based on a hole transport material (Hole Transport Layer—HTL) was found to be equal to 40 nm.

A material useful for improving wettability was deposited on the substrate thus obtained. For this purpose, a solution of poly[(9,9-bis(3′-(N,N-dimethylamino)propyl)-2,7-fluorene)-alt-2,7-(9,9-dioctylfluorene)] (PFN) (Aldrich) in methanol (purity 99.5%—Aldrich) at a concentration of 0.1 mg/ml, was deposited, by spin coating operating at a rotation speed of 5000 rpm (acceleration equal at 1000 rpm/s), for 40 seconds, then the whole was subjected to heat treatment (annealing), at 100° C., for 5 minutes.

Subsequently, the substrate obtained was placed in a dry box and the layer of methylammonium lead iodide (CH₃NH₃PbI₃) and polyacrylic acid partially neutralized with cesium (PACs5) obtained in Example 1, was deposited on top of the layer based on a material useful for improving the wettability, operating as follows. For this purpose, lead iodide (PbI₂) (ultra dry purity 99.999%—Alfa Aesar) (350.5 mg-0.76 mmol), methylammonium iodide (MAI) (CH₃NH₃ I) (GreatCell Solar) (120.8 mg-0.76 mmol) and polyacrylic acid partially neutralized with cesium (PACs5) (23.6 mg), were dissolved in anhydrous dimethyl sulfoxide (purity 99.9%—Aldrich) (1 ml), operating under stirring, at a temperature of 80° C., for 3 hours, obtaining a solution containing 30% by weight of perovskite precursors and 1.5% by weight of polyacrylic acid partially neutralized with cesium (PACs5), i.e. 5% by weight of polyacrylic acid partially neutralized with cesium (PACs5) with respect to the total weight of the other solid components (i.e. lead iodide (PbI₂)+methylammonium iodide (MAI) (CH₃NH₃I). The solution thus obtained has been deposited on said layer based on a material useful for improving wettability, by means of spin coating operating at a rotation speed equal to 5000 rpm (acceleration equal to 1000 rpm/s), for 20 seconds and the whole was subjected heat treatment (annealing), at 100° C., for 20 minutes. The thickness of the perovskite and polyacrylic acid (PAA) layer was found to be 325 nm.

The substrate thus obtained was ready for the deposition of the layer based on an electron transport material (Electron Transport Layer—ETL). For this purpose, a filtered solution of methyl ester of [6,6]-phenyl-C₆₁-butyric acid (PC₆₁BM) (Nano-C Products) (25 mg) in anhydrous chlorobenzene (purity 99.8%—Aldrich) (1 ml), was deposited, by means of spin coating operating at a rotation speed equal to 1000 rpm (acceleration equal to 500 rpm/s), for 60 seconds: the substrate obtained was left to rest, at ambient temperature (25° C.), for 10 minutes. The thickness of the layer based on an electron transport material (Electron Transport Layer—HTL) was found to be equal to 50 nm.

The substrate thus obtained was ready for the deposition of the layer based on a hole blocking material (Hole Blocking Layer—HBL). For this purpose, a solution of 2,9-dimethyl-4,7-diphenyl-1,10-phenatroline (Batocuproine—BCP) (purity 96%—Aldrich) (9 mg) in anhydrous iso-propyl alcohol (purity 99.5%—Aldrich) (18 ml) obtained by operating under stirring at 80° C., for 3 hours, was deposited, by spin coating by operating at a rotation speed equal to 6000 rpm (acceleration equal to 1000 rpm/s), for 20 seconds, the obtained substrate was left to rest, at room temperature (25° C.), for 5 minutes. The thickness of the layer based on a hole blocking material (Hole Blocking Layer—HBL) was found to be equal to 5 nm.

Subsequently, above said layer based on a hole blocking material (Hole Blocking Layer—HBL), the back contact (cathode) in metallic aluminum (Al) was deposited by evaporation. For this purpose, a Kurt J. Lesker evaporator was used, operating at a pressure equal to 2×10⁻⁶ mmHg and at a speed equal to 0.1 Angstrom/sec, suitably masking the area of the solar cell in order to obtain an area active equal to 4 mm². The thickness of the back contact (cathode) in metallic aluminum (Al), was found to be equal to 50 nm.

The thicknesses were measured by scanning electron microscopy using a Jeol 7600f scanning electron microscope (SEM), equipped with a field emission electron gun, operating with an accelerating voltage comprised between 1 kV and 5 kV, and exploiting the signal coming from secondary electrons.

The electrical characterization of the perovskite-based solar cell thus obtained was carried out at room temperature (25° C.). Current-voltage density (JV) curves were acquired with a Keithley® 2400 digital multimeter connected to a personal computer for data collection. The photocurrent was measured by exposing the solar cell to the light of a Newport 91160A solar simulator (Newport Corp), placed at a distance of 10 mm from said solar cell, equipped with a 300 W Xenon light source, using an illumination equal to 100 mm×100 mm: Table 1 shows the characteristic parameters as average values.

The light intensity was calibrated with a standard silicon solar cell (VLSI Standard—SRC-100-RTD-KG5).

In particular, Table 1 shows, in order: the number of the reference Example; the composition of the photoactive layer of perovskite and partially neutralized polyacrylic acid; FF (Fill Factor—filling factor); Voc (Open Circuit Voltage); Jsc (short-circuit photocurrent density); PCE (Power Conversion Efficiency).

### Example 10

### Preparation of a Perovskite-Based Solar Cell

The perovskite-based solar cell was obtained using the same procedure reported in Example 9, with the only difference deriving from the use of perovskite precursors and of partially neutralized polyacrylic acid containing a different amount of cesium.

For this purpose, lead iodide (PbI₂) (ultra dry purity 99.999%—Alfa Aesar) (350.5 mg-0.76 mmol), methylammonium iodide (MAI) (CH₃NH₃I) (GreatCell Solar) (120.8 mg-0.76 mmol) and the polyacrylic acid partially neutralized with cesium (PACs10) obtained in Example 2 (23.6 mg), were dissolved in anhydrous dimethylsulfoxide (purity 99.9%—Aldrich) (1 ml), operating under stirring, at a temperature of 80° C., for 3 hours, obtaining a solution containing 30% by weight of perovskite precursors and 1.5% by weight of polyacrylic acid partially neutralized with cesium (PACs10), i.e. 5% by weight of polyacrylic acid partially neutralized with cesium (PACs10) with respect to the total weight of the other solid components (i.e. lead iodide (PbI₂)+methylammonium iodide (MAI) (CH₃NH₃I)).

The electrical characterization of the perovskite-based solar cell obtained was carried out as described above: in Table 1, the characteristic parameters are reported as average values.

### Example 11

### Preparation of a Perovskite-Based Solar Cell

The perovskite-based solar cell was obtained using the same procedure reported in Example 9, with the only difference deriving from the use of perovskite precursors and of partially neutralized polyacrylic acid containing a different amount of cesium.

For this purpose, lead iodide (PbI₂) (ultra dry purity 99.999%—Alfa Aesar) (350.5 mg-0.76 mmol), methylammonium iodide (MAI) (CH₃NH₃I) (GreatCell Solar) (120.8 mg-0.76 mmol) and the polyacrylic acid partially neutralized with cesium (PACs20) obtained in Example 3 (23.6 mg), were dissolved in anhydrous dimethyl sulfoxide (purity 99.9%—Aldrich) (1 ml), operating under stirring, at a temperature of 80° C., for 3 hours, obtaining a solution containing 30% by weight of perovskite precursors and 1.5% by weight of polyacrylic acid partially neutralized with cesium (PACs20), i.e. 5% by weight of polyacrylic acid partially neutralized with cesium (PACs20) with respect to the total weight of the other solid components (i.e. lead iodide (PbI₂)+methylammonium iodide (MAI) (CH₃NH₃I)).

The electrical characterization of the perovskite-based solar cell obtained was carried out as described above: in Table 1, the characteristic parameters are reported as average values.

### Example 12

### Preparation of a Perovskite-Based Solar Cell

The perovskite-based solar cell was obtained using the same procedure reported in Example 9, with the only difference deriving from the use of perovskite precursors and of partially neutralized polyacrylic acid containing a different amount of cesium.

For this purpose, lead iodide (PbI₂) (ultra dry purity 99.999%—Alfa Aesar) (350.5 mg-0.76 mmol), methylammonium iodide (MAI) (CH₃NH₃I) (GreatCell Solar) (120.8 mg-0.76 mmol) and the polyacrylic acid partially neutralized with cesium (PACs40) obtained in Example 4 (23.6 mg), were dissolved in anhydrous dimethylsulfoxide (purity 99.9%—Aldrich) (1 ml), operating under stirring, at a temperature of 80° C., for 3 hours, obtaining a solution containing 30% by weight of perovskite precursors and 1.5% by weight of polyacrylic acid partially neutralized with cesium (PACs40), i.e. 5% by weight of polyacrylic acid partially neutralized with cesium (PACs40) with respect to the total weight of the other solid components (i.e. lead iodide (PbI₂)+methylammonium iodide (MAI) (CH₃NH₃I)).

The electrical characterization of the perovskite-based solar cell obtained was carried out as described above: in Table 1, the characteristic parameters are reported as average values.

TABLE 1

| | | FF ⁽¹⁾ | Voc ⁽²⁾ | Jsc ⁽³⁾ | PCE ⁽⁴⁾ |
|---|---|---|---|---|---|
| Example | Photoactive layer | (%) | (V) | (mA/cm²) | (%) |
| 9 | CH₃NH₃PbI₃(30)⁽⁵⁾ + PACs5 | 73.8 | 1.14 | 19.2 | 16.1 |
| | (5) ⁽⁶⁾ | | | | |
| 10 | CH₃NH₃PbI₃(30) ⁽⁵⁾ + PACs10 | 76.7 | 1.11 | 16.3 | 13.9 |
| | (5) ⁽⁶⁾ | | | | |
| 11 | CH₃NH₃PbI₃(30) ⁽⁵⁾ + PACs20 | 74.9 | 1.11 | 15.5 | 13.0 |
| | (5) ⁽⁶⁾ | | | | |
| 12 | CH₃NH₃PbI₃(30) ⁽⁵⁾ + PACs40 | 75.4 | 1.13 | 18.5 | 15.8 |
| | (5) ⁽⁶⁾ | | | | |

⁽¹⁾ Fill Factor;
⁽²⁾ Open Circuit Voltage;
⁽³⁾ short-circuit photocurrent density;
⁽⁴⁾ Power Conversion Efficiency;
⁽⁵⁾ methylammonium lead iodide [(CH₃NH₃)PbI₃] [(in brackets % by weight of perovskite precursors (i.e. lead iodide (PbI₂) + methylammonium iodide (MAI) (CH₃NH₃I)];
⁽⁶⁾ partially neutralized polyacrylic acid (in brackets % by weight of partially neutralized polyacrylic acid with respect to the total weight of the other solid components [i.e. lead iodide (PbI₂) + methylammonium iodide (MAI)(CH₃NH₃I)].

From the data reported in Table 1, it can be seen that the perovskite-based solar cell of the present disclosure has both a good power conversion efficiency (PCE) (i.e. PCE>10%), and good electrical properties, i.e. good values of FF (filling factor), Voc (Open Circuit Voltage); Jsc (short-circuit photocurrent density).

### Example 13

### Preparation of a Perovskite-Based Solar Cell

The perovskite-based solar cell was obtained using the same procedure reported in Example 9, with the only difference deriving from the use of perovskite precursors and of polyacrylic acid partially neutralized with potassium.

For this purpose, lead iodide (PbI₂) (ultra dry purity 99.999%—Alfa Aesar) (350.5 mg-0.76 mmol), methylammonium iodide (MAI) (CH₃NH₃I) (GreatCell Solar) (120.8 mg-0.76 mmol) and the polyacrylic acid partially neutralized with potassium (PAK5) obtained in Example 5 (23.6 mg), were dissolved in anhydrous dimethylsulfoxide (purity 99.9%—Aldrich) (1 ml), operating under stirring, at a temperature of 80° C., for 3 hours, obtaining a solution containing 30% by weight of perovskite precursors and 1.5% by weight of polyacrylic acid partially neutralized with potassium (PAK5), i.e. 5% by weight of polyacrylic acid partially neutralized with potassium (PAK5) with respect to the total weight of the other solid components (i.e. lead iodide (PbI₂)+methylammonium iodide (MAI) (CH₃NH₃I)).

The electrical characterization of the perovskite-based solar cell obtained was carried out as described above: in Table 2, the characteristic parameters are reported as average values.

In particular, Table 2 shows, in order: the number of the reference Example; the composition of the photoactive layer of perovskite and partially neutralized polyacrylic acid; FF (filling factor); Voc (Open Circuit Voltage); Jsc (short-circuit photocurrent density); PCE (Power Conversion Efficiency).

### Example 14

### Preparation of a Perovskite-Based Solar Cell

The perovskite-based solar cell was obtained using the same procedure reported in Example 9, with the only difference deriving from the use of perovskite precursors and of partially neutralized polyacrylic acid containing a different amount of potassium compared to Example 13.

For this purpose, lead iodide (PbI₂) (ultra dry purity 99.999%—Alfa Aesar) (350.5 mg-0.76 mmol), methylammonium iodide (MAI) (CH₃NH₃I) (GreatCell Solar) (120.8 mg-0.76 mmol) and the polyacrylic acid partially neutralized with potassium (PAK10) obtained in Example 6 (23.6 mg), were dissolved in anhydrous dimethyl sulfoxide (purity 99.9%—Aldrich) (1 ml), operating under stirring, at a temperature of 80° C., for 3 hours, obtaining a solution containing 30% by weight of perovskite precursors and 1.5% by weight of a polyacrylic acid partially neutralized with potassium (PAK10), i.e. 5% by weight of polyacrylic acid partially neutralized with potassium (PAK10) with respect to the total weight of the other solid components (i.e. lead iodide (PbI₂)+methylammonium iodide (MAI) (CH₃NH₃I)).

The electrical characterization of the perovskite-based solar cell obtained was carried out as described above: in Table 2, the characteristic parameters are reported as average values.

### Example 15

### Preparation of a Perovskite-Based Solar Cell

The perovskite-based solar cell was obtained using the same procedure reported in Example 9, with the only difference deriving from the use of perovskite precursors and of partially neutralized polyacrylic acid containing a different amount of potassium compared to Example 13 and at different concentrations with respect to the total weight of the other solid components (i.e. lead iodide (PbI₂)+methylammonium iodide (MAI) (CH₃NH₃I)).

For this purpose, lead iodide (PbI₂) (ultra dry purity 99.999%—Alfa Aesar) (350.5 mg-0.76 mmol), methylammonium iodide (MAI) ((CH₃NH₃I)) (GreatCell Solar) (120.8 mg-0.76 mmol) and the polyacrylic acid partially neutralized with potassium (PAK5) obtained in Example 5 (47.2 mg), were dissolved in anhydrous dimethyl sulfoxide (purity 99.9%—Aldrich) (1 ml), operating under stirring, at a temperature of 80° C., for 3 hours, obtaining a solution containing 30% by weight of perovskite precursors and 3.0% by weight of polyacrylic acid partially neutralized with potassium (PAK5), i.e. 10% by weight of polyacrylic acid partially neutralized with potassium (PAK5) with respect to the total weight of the other solid components (i.e. lead iodide (PbI₂)+methylammonium iodide (MAI) (CH₃NH₃I)).

The electrical characterization of the perovskite-based solar cell obtained was carried out as described above: in Table 2, the characteristic parameters are reported as average values.

TABLE 2

| | | FF ⁽¹⁾ | Voc ⁽²⁾ | Jsc ⁽³⁾ | PCE ⁽⁴⁾ |
|---|---|---|---|---|---|
| Example | Photoactive layer | (%) | (V) | (mA/cm²) | (%) |
| 13 | CH₃NH₃PbI₃(30) ⁽⁵⁾ + PAK5 | 77.1 | 1.15 | 17.2 | 15.2 |
| | (5) ⁽⁶⁾ | | | | |
| 14 | CH₃NH₃PbI₃(30) ⁽⁵⁾+ PAK10 | 72.9 | 1.15 | 12.7 | 10.6 |
| | (5) ⁽⁶⁾ | | | | |
| 15 | CH₃NH₃PbI₃(30) ⁽⁵⁾ + PAK5 | 73.5 | 1.18 | 15.1 | 13.1 |
| | (10) ⁽⁶⁾ | | | | |

⁽¹⁾ Fill Factor;
⁽²⁾ Open Circuit Voltage;
⁽³⁾ short-circuit photocurrent density;
⁽⁴⁾ Power Conversion Efficiency;
⁽⁵⁾ methylammonium lead iodide [(CH₃NH₃)PbI₃] [(in brackets % by weight of perovskite precursors (i.e. lead (PbI₂) + methylammonium iodide (MAI) (CH₃NH₃I)]);
⁽⁶⁾ partially neutralized polyacrylic acid (in brackets % by weight of partially neutralized polyacrylic acid with respect to the total weight of the other solid components [i.e. lead iodide (PbI₂) + methylammonium iodide (MAI) (CH₃NH₃I)].

From the data reported in Table 2, it can be seen that the perovskite-based solar cell of the present disclosure shows to have both a good Power Conversion Efficiency (PCE) (i.e. PCE>10%), and good electrical properties, i.e. good values of FF (filling factor), Voc (Open Circuit Voltage); Jsc (short-circuit photocurrent density).

1. A perovskite based photovoltaic cell (or solar cell) wherein the photoactive layer of perovskite comprises at least one partially neutralized polyacrylic acid in an amount greater than or equal to 3% by weight, with respect to the total weight of the perovskite precursors.

2. The perovskite based photovoltaic cell (or solar cell) according to claim 1, wherein said perovskite is selected from organometallic trihalides having general formula ABX₃ wherein:
A represents a monovalent organic cation such as methylammonium (CH₃NH₃⁺), formamide [CH(NH₂)₂⁺], n-butylammonium (C₄H₁₂N⁺), tetra-butylammonium (C₁₆H₃₆N⁺), or mixtures thereof; or A represents a monovalent inorganic cation such as cesium (Cs⁺), rubidium (Rb⁺), potassium (K⁺), lithium (Li⁺), sodium (Na⁺), copper (Cu⁺), silver (Ag⁺), or mixtures thereof; or mixtures thereof;
B represents a divalent metal cation such as lead (Pb²⁺), tin (Sn²⁺), or mixtures thereof; and
X represents a halide anion such as iodine (I⁻), chlorine (Cl⁻), bromine (Br⁻), or mixtures thereof.

3. The perovskite based photovoltaic cell (or solar cell) according to claim 1, wherein said perovskite is selected from: methylammonium lead iodide (CH₃NH₃PbI₃), methylammonium lead bromide (CH₃NH₃PbBr₃), methylammonium lead chloride (CH₃NH₃PbCl₃), methylammonium lead iodide bromide (CH₃NH₃PbIₓBr₃₋ₓ), methylammonium lead iodide chloride (CH₃NH₃PbIₓCl₃₋ₓ), formamide lead iodide [CH(NH₂)₂PbI₃], formamide lead bromide [CH(NH₂)₂PbBr₃], formamide lead chloride [CH(NH₂)₂PbCl₃], formamide lead iodide bromide [CH(NH₂)₂PbIₓBr₃₋ₓ], formamide lead iodide chloride [CH(NH₂)₂PbIₓCl₃₋ₓ], methylammonium formamide lead iodide [(CH₃NH₃)ₓ(CH(NH₂)₂)₁₋ₓPbI₃], methylammonium formamide lead bromide [(CH₃NH₃)ₓ(CH(NH₂)₂)₁₋ₓPbBr₃], methylammonium formamide lead chloride [(CH₃NH₃)ₓ(CH(NH₂)₂)₁₋ₓPbCl₃], methylammonium formamide lead iodide chloride [(CH₃NH₃)ₓ(CH(NH₂)₂)₁₋ₓPbI_{3-y}Cl_{y}], methylammonium formamide lead iodide bromide [(CH₃NH₃)ₓ(CH(NH₂)₂)₁₋ₓPbI_{3-y}Br_{y}], n-butylammonium lead iodide (C₄H₁₂NH₃PbI₃), tetra-butylammonium lead iodide (C₁₆H₃₆NPbI₃), n-butylammonium lead bromide (C₄H₂NH₃PbBr₃), tetra-butylammonium lead bromide (C₁₆H₃₆NPbBr₃), cesium lead iodide (CsPbI₃), rubidium lead iodide (RbPbI₃), potassium lead iodide (KPbI₃), cesium methylammonium lead iodide [Csₓ(CH₃NH₃)₁₋ₓPbI₃], potassium methylammonium lead iodide [Kₓ(CH₃NH₃)₁₋ₓPbI₃], cesium methylammonium lead iodide chloride [Csₓ(CH₃NH₃)₁₋ₓPbI_{3-y}Cl_{y}], cesium formamide lead iodide [Csₓ(CH(NH₂)₂)₁₋ₓPbI₃], cesium formamide lead bromide [Csₓ(CH(NH₂)₂)₁₋ₓPbBr₃], cesium formamide lead iodide chloride [Csₓ(CH(NH₂)₂)₁₋ₓPbI_{3-y}Cl_{y}], methylammonium tin iodide (CH₃NH₃SnI₃), methylammonium tin bromide (CH₃NH₃SnBr₃), methylammonium tin iodide bromide (CH₃NH₃SnIₓBr₃₋ₓ), formamide tin iodide [CH(NH₂)₂SnI₃], formamide tin iodide bromide [CH(NH₂)₂SnIₓBr₃₋ₓ], n-butylammonium tin iodide (C₄H₁₂NH₃ SnI₃), tetra-butylammonium tin iodide (C₁₆H₃₆NSnI₃), n-butylammonium tin bromide (C₄H₁₂NH₃SnBr₃), tetra-butylammonium tin bromide (C₁₆H₃₆NSnBr₃), methylammonium tin lead iodide (CH₃NH₃SnₓPb₁₋ₓI₃), formamide tin lead iodide [CH(NH₂)₂SnₓPb₁₋ₓI₃], or mixtures thereof; preferably is selected from methylammonium lead iodide (CH₃NH₃PbI₃), formamide lead iodide [CH(NH₂)₂PbI₃], methylammonium formamide lead iodide chloride [(CH₃NH₃)ₓ (CH(NH₂)₂)₁₋ₓPbI_{3-y}Cl_{y}], cesium methylammonium lead iodide chloride [Csₓ(CH₃NH₃)₁₋ₓPbI_{3-y}Cl_{y}], cesium formamide lead iodide chloride [Csₓ(CH(NH₂)₂)₁₋ₓPbI_{3-y}Cl_{y}]; more preferably is methylammonium lead iodide (CH₃NH₃PbI₃).

4. The perovskite based photovoltaic cell (or solar cell) according to claim 1, wherein said polyacrylic acid has a general formula (I): 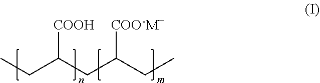
wherein:
n and m are integers and:
the sum n+m is comprised between 10 and 60000;
the ratio n:m is comprised between 99:1 and 1:99;
M⁺ represents a monovalent metal cation selected from alkali metals such as lithium (Li⁺), sodium (Na⁺), potassium (K⁺), rubidium (Rb⁺), cesium (Cs⁺), preferably lithium (Li⁺), potassium (K⁺), rubidium (Rb⁺), cesium (Cs⁺), more preferably potassium (K⁺), cesium (Cs⁺); or from other monovalent metals such as copper (Cu⁺), silver (Ag⁺), gold (Au⁺), mercury (Hg⁺), thallium (Tl⁺), preferably copper (Cu⁺), silver (Ag⁺);
or M⁺ represents a monovalent cation having general formula (II): 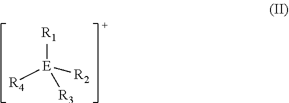
wherein:
E represents a nitrogen atom, a phosphorus atom;
R₁, R₂, R₃, and R₄ identical or different from each other, represent a hydrogen atom; or are selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups;
or R₁ and R₂, and/or R₂ and R₃, and/or R₃ and R₄, and/or R₄ and R₁, can possibly be bonded together so as to form, together with the other atoms to which they are bonded, a saturated, unsaturated, or aromatic cycle containing from 2 to 12 carbon atoms, optionally substituted with C₁-C₂₀, preferably C₁-C₁₂, linear or branched, saturated or unsaturated, optionally containing heteroatoms alkyl groups, optionally substituted aryl groups, optionally substituted heteroaryl groups, optionally substituted cycloalkyl groups, optionally substituted heterocyclic groups, trialkyl- or triaryl-silyl groups, dialkyl- or diaryl-amino groups, dialkyl- or diaryl-phosphinic groups, C₁-C₂₀, preferably C₂-C₁₀, linear or branched, saturated or unsaturated alkyl groups, optionally substituted aryloxy groups, optionally substituted thioalkoxyl or thioaryloxy groups, cyano groups, said cycle optionally containing heteroatoms such as oxygen, sulfur, nitrogen, silicon, phosphorus, selenium, preferably oxygen, nitrogen;
or M⁺ represents a monovalent cation having general formula (III): 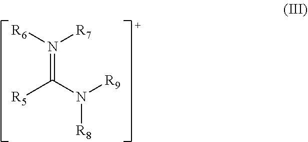
wherein:
R₅ represents a hydrogen atom; or represents a halogen atom such as fluorine, chlorine bromine, iodine, preferably fluorine, chlorine; or is selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups; preferably R₅ is hydrogen or methyl;
R₆, R₇, R₈ and R₉ identical or different from each other, represent a hydrogen atom; or are selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups;
or R₇ and R₈, and/or R₉ and R₁₀ can be possibly bonded together so as to form, together with the other atoms to which they are bonded a saturated, unsaturated, or aromatic cycle containing from 2 to 12 carbon atoms, optionally substituted with linear or branched C₁-C₂₀, saturated or unsaturated, optionally containing heteroatoms alkyl groups, optionally substituted aryl groups, optionally substituted heteroaryl groups, optionally substituted cycloalkyl groups, optionally substituted heterocyclic groups, trialkyl- or triaryl-silyl groups, dialkyl- or diaryl-amino groups, dialkyl- or diaryl-phosphinic groups, C₁-C₂₀, preferably C₂-C₁₀, linear or branched, saturated or unsaturated alkoxy groups, optionally substituted aryloxyl groups, optionally substituted thioalkoxyl or thioaryloxyl groups, cyano groups, said cycle optionally containing heteroatoms such as oxygen, sulfur, nitrogen, silicon, phosphorus, selenium, preferably and oxygen, nitrogen; preferably R₆, R₇, R₈ and R₉ represent a hydrogen atom.

5. The perovskite based photovoltaic cell (or solar cell) according to claim 1, wherein in said partially neutralized polyacrylic acid free carboxylic groups are present in an amount comprised between 1% and 99, with respect to the total quantity of carboxylic groups present in said polyacrylic acid.

6. The perovskite based photovoltaic cell (or solar cell) according to claim 1, wherein the starting polyacrylic acid (i.e. not neutralized) has a weight average molecular weight (M_{w}) comprised between 700 Da and 4000000 Da.

7. The perovskite based photovoltaic cell (or solar cell) according to claim 1, comprising:
a glass substrate covered with a transparent and conductive oxide layer (Transparent Conductive Oxide—TCO), generally fluorine-doped tin oxide (SnO₂:F) (FTO), or indium tin oxide (ITO) which constitutes the anode;
a layer based on a hole-carrying material (Hole Transport Layer—HTL), preferably a layer of poly[bis(4-butylphenyl)-bisphenylbenzidine] (Poly-TPD);
optionally a layer based on a material useful for improving wettability, preferably a layer of poly[9,9-bis(3′-(N,N-dimethyl)-N-ethylammonium-propyl-2,7-fluorene)-alt-2,7-(9,9-dioctylfluorene)]diiodide (PFN-I), or a layer of poly[9,9-bis(3′-(N,N-dimethyl)-N-ethylammonium-propyl-2,7-fluorene)-alt-2,7-(9,9-dioctylfluorene)](PFN);
a photoactive layer comprising at least one perovskite, preferably methylammonium lead iodide (CH₃NH₃PbI₃) [methylammonium lead iodide (CH₃NH₃PbI₃) is the most used structure as it has a high absorption coefficient throughout the UV and visible spectrum, a “band-gap” equal to 1.57 eV, close to the optimal value to maximize conversion efficiency and a considerable diffusion distance of electrons and electronic holes (or holes) (over 100 nm)], and at least one partially neutralized polyacrylic acid, preferably a partially neutralized polyacrylic acid with cesium or potassium, having an amount of free carboxylic groups comprised between 60% and 95%;
a layer based on an electron-carrying material (Electron Transport Layer—ETL), preferably a layer of methyl ester of [6,6]-phenyl-C₆₁-butyric acid (PC₆₁BM);
optionally, a layer based on a hole blocking material (HBL), preferably a layer of 2,9-dimethyl-4,7-diphenyl-1,10-phenanthroline (Batocuproin—BCP) or polyethylenimine ethoxylated (PEIE);
a metallic contact known as a back contact which constitutes the cathode, preferably a layer of metallic gold, silver, or aluminum.

8. The perovskite-based photovoltaic cell (or solar cell) according to claim 1, wherein the electrical energy generated by said at least one perovskite-based photovoltaic cell (or solar cell) is transported using a wiring system which is connected with said perovskite based photovoltaic cell (or solar cell).

9. A process for preparing a perovskite based photovoltaic cell (or solar cell) including the following steps:
(a) preparing a glass substrate coated with a transparent and conductive oxide layer (Transparent Conductive Oxide—TCO) (anode);
(b) depositing a layer based on a hole-carrying material (Hole Transport Layer—HTL) on the substrate obtained in said step (a);
(c) optionally, depositing on the base layer of a hole-carrying material (Hole Transport Layer—HTL) obtained in said step (b) a layer based on a material useful for improving wettability;
(d) preparing a mixture comprising precursors of perovskite and at least one partially neutralized polyacrylic acid, said partially neutralized polyacrylic acid being present in said mixture in an amount greater than or equal to 3% by weight, with respect to the total weight of the perovskite precursors;
(e) depositing the mixture obtained in said step (d) on the layer based on a hole-carrying material (Hole Transport Layer—HTL) obtained in said step (b), or on the layer based on a material to improve wettability obtained in said step (c), obtaining a photoactive layer;
(f) depositing a layer based on an electron-carrying material (Electron Transport Layer—ETL), on the photoactive layer obtained in said step (e);
(g) optionally, depositing on the base layer of an electron-carrying material (Electron Transport Layer—ETL) obtained in said step (f), a layer based on a material for blocking holes (Hole Blocking Layer—HBL);
(h) depositing a metallic contact known as a back contact which constitutes the cathode, on the layer based on an electron-carrying material (Electron Transport Layer—ETL) obtained in said step (f), or on the layer based on a material for blocking holes (Hole Blocking Layer—HBL) obtained in said step (g);
wherein said steps (b), (c), (e), (f) and (g), are carried out at a temperature lower than 120° C.

10. Use of a perovskite based photovoltaic cell (or solar cell) according to claim 9 in: architecturally integrated photovoltaic systems (Building Integrated Photo Voltaic—BIPV); photovoltaic windows; greenhouses; photo-bioreactors; noise barriers; lighting engineering; design; advertising; and automotive industry.

11. A composition comprising at least one perovskite and at least one partially neutralized polyacrylic acid in an amount greater than or equal to 3% by weight, with respect to the total weight of the perovskite precursors.

12. The composition according to claim 11, wherein said perovskite is selected from organometallic trihalides having general formula ABX₃ wherein:
A represents a monovalent organic cation such as methylammonium (CH₃NH₃⁺), formamide [CH(NH₂)₂⁺], n-butylammonium (C₄H₁₂N⁺), tetra-butylammonium (C₁₆H₃₆N⁺), or mixtures thereof; or A represents a monovalent inorganic cation such as cesium (Cs⁺), rubidium (Rb⁺), potassium (K⁺), lithium (Li⁺), sodium (Na⁺), copper (Cu⁺), silver (Ag⁺), or mixtures thereof; or mixtures thereof;
B represents a divalent metal cation such as lead (Pb²⁺), tin (Sn²⁺), or mixtures thereof; and
X represents a halide anion such as iodine (I⁻), chlorine (Cl⁻), bromine (Br⁻), or mixtures thereof;
and said partially neutralized polyacrylic acid has a general formula (I): 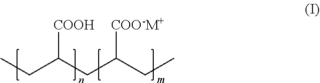
wherein:
n and m are integers and:
the sum n+m is comprised between 10 and 60000;
the ratio n:m is comprised between 99:1 and 1:99;
M⁺ represents a monovalent metal cation selected from alkali metals such as lithium (Li⁺), sodium (Na⁺), potassium (K⁺), rubidium (Rb⁺), cesium (Cs⁺), preferably lithium (Li⁺), potassium (K⁺), rubidium (Rb⁺), cesium (Cs⁺), more preferably potassium (K⁺), cesium (Cs⁺); or from other monovalent metals such as copper (Cu⁺), silver (Ag⁺), gold (Au⁺), mercury (Hg⁻), thallium (Tl⁺), preferably copper (Cu⁺), silver (Ag⁺);
or M⁺ represents a monovalent cation having general formula (II): 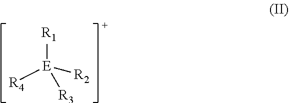
wherein:
E represents a nitrogen atom, a phosphorus atom;
R₁, R₂, R₃, and R₄ identical or different from each other, represent a hydrogen atom; or are selected from C₁-C₂₀, preferably C₁-C₁₂, linear or branched, saturated or unsaturated, optionally containing heteroatoms alkyl groups: optionally substituted aryl groups; optionally substituted heteroaryl groups; optionally substituted cycloalkyl groups; optionally substituted heterocyclic groups;
or R₁ and R₂, and/or R₂ and R₃, and/or R₃ and R₄, and/or R₄ and R₁, can possibly be bonded together so as to form, together with the other atoms to which they are bonded, a saturated, unsaturated, or aromatic cycle containing from 2 to 12 carbon atoms, optionally substituted with C₁-C₂, preferably C₁-C₁₂, linear or branched, saturated or unsaturated, optionally containing heteroatoms alkyl groups, optionally substituted aryl groups, optionally substituted heteroaryl groups, optionally substituted cycloalkyl groups, optionally substituted heterocyclic groups, trialkyl- or triaryl-silyl groups, dialkyl- or diaryl-amino groups, dialkyl- or diaryl-phosphinic groups, C₁-C₂₀, preferably C₂-C₁₀, linear or branched, saturated or unsaturated alkyl groups, optionally substituted aryloxy groups, optionally substituted thioalkoxyl or thioaryloxy groups, cyano groups, said cycle optionally containing heteroatoms such as oxygen, sulfur, nitrogen, silicon, phosphorus, selenium, preferably oxygen, nitrogen;
or M⁺ represents a monovalent cation having general formula (III): 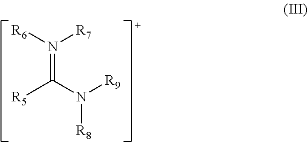
wherein:
R₅ represents a hydrogen atom; or represents a halogen atom such as fluorine, chlorine bromine, iodine, preferably fluorine, chlorine; or is selected from C₁-C₂₀, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups; preferably R₅ is hydrogen or methyl;
R₆, R₇, R₈ and R₉identical or different from each other, represent a hydrogen atom; or are selected from C₁-C₂, preferably C₁-C₁₂, linear or branched, saturated or unsaturated, optionally containing heteroatoms alkyl groups; optionally substituted aryl groups; optionally substituted heteroaryl groups; optionally substituted cycloalkyl groups; optionally substituted heterocyclic groups;
or R₇ and R₈, and/or R₉ and R₁₀ can be possibly bonded together so as to form, together with the other atoms to which they are bonded a saturated, unsaturated, or aromatic cycle containing from 2 to 12 carbon atoms, optionally substituted with linear or branched C₁-C₂₀, saturated or unsaturated, optionally containing heteroatoms alkyl groups, optionally substituted aryl groups, optionally substituted heteroaryl groups, optionally substituted cycloalkyl groups, optionally substituted heterocyclic groups, trialkyl- or triaryl-silyl groups, dialkyl- or diaryl-amino groups, dialkyl- or diaryl-phosphinic groups, C₁-C₂₀, preferably C₂-C₁₀, linear or branched, saturated or unsaturated alkoxy groups, optionally substituted aryloxyl groups, optionally substituted thioalkoxyl or thioaryloxyl groups, cyano groups, said cycle optionally containing heteroatoms such as oxygen, sulfur, nitrogen, silicon, phosphorus, selenium, preferably and oxygen, nitrogen; preferably R₆, R₇, R₈ and R₉ represent a hydrogen atom.
